(19) United States
(12) Patent Application Publication
(10) Pub. No.: US 2008/0042656 A1
(43) Pub. Date: Feb. 21, 2008

(54) Trailer light circuit testing device

(76) Inventor: Aaron R. Hall, Palisade, CO (US)

Correspondence Address: Galasso & Associates, LP, P.O. Box 26503, Austin, TX, 78755-0503, US

(21) Appl. No.: 11/502,195

(22) Filed: Aug. 10, 2006

(51) Int. Cl. G01R 31/00; G08B 21/00

(52) U.S. Cl. 324/500; 340/657; 340/431

(57) ABSTRACT

A trailer light testing device designed to test a plurality of lights on a conventional recreational vehicle trailer independent of the recreational vehicle being coupled to a tow vehicle's power supply. The trailer light testing device includes a housing with a terminal assembly disposed on one end of the housing. The terminal assembly includes a circuit with a seven electrical terminals configured to be mateably connected with a conventional seven-way plug of a trailer light system. The trailer light testing device further includes a switch for controlling at least two of the electrical terminal that are operably connected to the turn signal lights of the trailer. The housing further includes a lid mounted on one end proximate the terminal assembly.

### FIELD OF THE INVENTION

The present invention relates to a circuit testing device, more specifically but not by way of limitation, a circuit testing device that is designed to test the lights of a conventional tow trailer without having a vehicle connected thereto.

### BACKGROUND

Outdoor recreational activities are participated in by millions of individuals every year. These activities can range from hunting, boating and camping. In order to engage in these activities, individuals usually purchase or rent items such as camping trailers, boats or all terrain vehicles.

Most of the aforementioned items are often transported to the desired destination either as a trailer or on a trailer, with the trailer being designed to be towed with an appropriate vehicle such as an automobile or truck. A camping trailer or a typical trailer that is designed to transport items such as a boat or all terrain vehicle is equipped with the basic lights that are required by state law. A standard lighting system on a vehicle trailer will contain at a minimum rear tail lights and turn signal lights. Larger conventional fifth wheel trailers such as but not limited to camping trailers will have lighting systems that further contain marker lights and reverse indicator lights. The trailer light systems contain the conventional circuit that are necessary to operate the trailer lights when operably connected to a tow vehicle.

Routine inspection and testing of the trailer light circuits are necessary in order to abide with state law and for good safety habits. Normally, a vehicle trailer must be operably engaged with a tow vehicle in order to supply the necessary power and turn signal light flashing unit so that a complete test of the light circuits can be performed. This can create a significant inconvenience for any individual that is testing the trailer light circuits that does not have immediate access to a tow vehicle with the appropriate connections. Many owners of large camping trailers store the trailers at a storage facility and do not regularly drive an appropriate tow vehicle capable of towing the trailer. As owners must perform routine inspections of the lighting system this is very inconvenient.

Accordingly, there is a need for a device that is capable of allowing a user to test conventional trailer light circuits without the need of a tow vehicle.

### SUMMARY OF THE INVENTION

It is the object of the present invention to provide a device that can operably engage with a plurality of conventional tow trailer light connections that can test the conventional light circuits on the trailer without the need of a tow vehicle.

It is a further object of the present invention to provide a device that is capable of testing conventional trailer light circuits that further includes a power supply.

Another object of the present invention is to provide a device that operably engages with a plurality of conventional tow trailer light connection plugs in order to test the trailer lights and light circuits that further incorporates a conventional automotive signal flasher.

Yet another object of the present invention is to provide a device that operably engages with a plurality of conventional tow trailer light connection plugs that is portable and light weight.

A further object of the present invention is to provide a device that operably engages with a plurality of conventional tow trailer light connection plugs that is easy to use.

To the accomplishment of the above and related objects the present invention may be embodied in the form illustrated in the accompanying drawings. Attention is called to the fact that the drawings are illustrative only. Variations are contemplated as being a part of the present invention, limited only by the scope of the claims.

### BRIEF DESCRIPTION OF THE DRAWINGS

A more complete understanding of the present invention may be had by reference to the following Detailed Description and appended claims when taken in conjunction with the accompanying Drawing wherein:

FIG. 1 is a perspective view of a preferred embodiment of the present invention;

FIG. 2 is a schematic illustrating an embodiment of a trailer light testing circuit in accordance with the principles of the present invention; and

FIG. 3 is a schematic illustrating an alternative embodiment of a trailer light testing circuit in accordance with the principles of the present invention.

### DETAILED DESCRIPTION

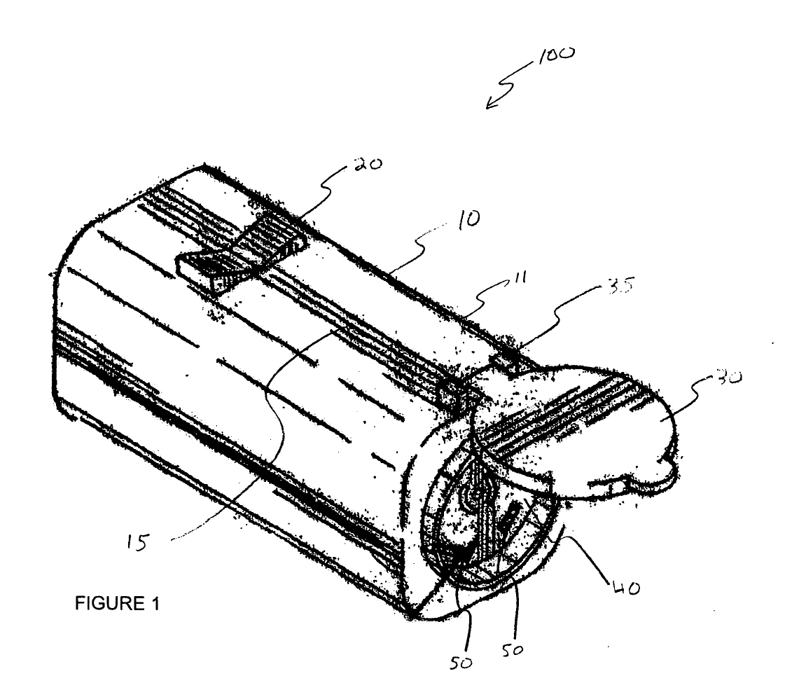

Referring now to the drawings submitted herewith wherein the various elements depicted therein are not necessarily drawn to scale and wherein like elements are identified with like reference numerals and in particular to FIGS. 1 through 3, there is illustrated preferred embodiments of a trailer light testing device 100.

Referring in particular to FIG. 1, the trailer light testing device 100 comprises a housing 10. The housing 10 is conventional container having at least one wall 11 defining an internal volume that is configured in a substantially rectangular shape and is constructed of a suitable durable material such as but not limited to plastic.

Mounted onto the top portion 15 of the housing 10 is a switch 20. The switch is operably connected to at least one of the plurality of terminal leads 50 that are mounted on the terminal assembly 40. The switch 20 functions as a conventional electric switch to control a portion of the terminal assembly circuit 200 disposed within the trailer light testing device 100. Although no specific type of switch 20 is necessary, good results have been achieved with a switch 20 that is manufactured from a conventional three-way switch.

Proximate the first end of the housing 10 is the terminal assembly 40. The terminal assembly 40 has integrally mounted thereon a plurality of terminal leads 50. The terminal leads 50 are conventional female trailer light receptacle terminals that are manufactured to interface with conventional light connection leads of a standard tow trailer light plug. The terminal assembly 40 is generally annular in shape and is configured to couple with a conventional seven-way plug of a trailer light system. Subsequent to engagement of the seven-way plug to the terminal assembly 40, the trailer light testing device 100 provides the adequate power to operate a plurality of standard lights configured on the trailer, such as the break lights, operating lights, reverse lights, and turning signal lights.

Although the terminal assembly 40 illustrated in the drawings submitted herewith is shown to be configured to be coupled with a conventional recreational camping trailer having a seven-way plug, it is contemplated within the scope of the present invention that the terminal assembly 40 could be configured to couple or mate with the shape of the targeted trailer light connection plug. More specifically but not by way of limitation, the terminal assembly 40 could be configured to couple with a conventional four-way or six-way plug.

A lid 30 is attached to the top portion 15 of the housing 10 proximate the first end via a hinge 35. The lid 30 is configured in a generally planar manner and is designed to cover the terminal assembly 40 when light testing device 100 is not being used and further designed to be easily opened to expose terminal assembly 40. The lid 30 further functions to help releasably secure a conventional trailer light plug that is engaged with the terminal assembly 40. The lid 30 is manufactured from a suitable durable material such as but not limited to plastic. Although the lid 30 is shown as being generally annular in shape, it is further contemplated within the scope of the present invention that lid 30 could be a plurality of shapes and still achieve the desired function as described herein.

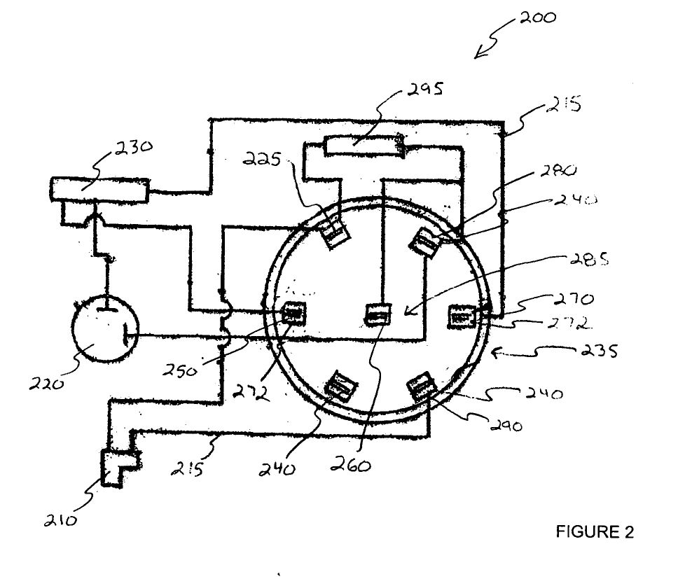

Referring now in particular to FIG. 2, there is illustrated a preferred embodiment of a terminal assembly circuit 200 such as would be embodied by light testing device 100. As illustrated, the terminal assembly circuit 200 includes a power supply interface 210; flashing unit 220, a three-way switch 230, terminals 240, fuse 295, wire 215 and power supply terminal 225.

The terminal assembly circuit 200 is integrated into a conventional seven-way plug 235 containing a plurality of terminals 240. The terminals 240 are conventional female receptacles that are manufactured of electrically conductive material according to standard practices to those skilled in the art. The terminals 240 are of suitable size and shape to mate with a conventional seven-way plug of a trailer light system. A power supply is electrically coupled to the terminal assembly circuit 200 via the power supply interface 210. The power supply interface 210 is designed for releasably engaging with a conventional twelve volt power supply such as but not limited to a twelve volt DC battery typically used on recreational camping trailer or tow vehicles. Those skilled in the art will recognize that numerous different power supplies could be utilized to supply power to the terminal assembly circuit 200. Although the power supply interface 210 is illustrated as a two way plug, it is further contemplated within the scope of the present invention that the power supply interface 210 could be constructed of conventional electrical clips designed to couple with the positive and negative terminals of a twelve volt DC battery.

The power supply interface 210 is electrically coupled to the power terminal 225 and all of the terminals 240 utilizing wire 215 constructed of electrically conductive material according to standard practices known to those skilled in the art. The power supply interface 210 engages with an appropriate power supply in order to provide the needed power to operate and test conventional trailer lights that are electrically coupled to the terminal assembly circuit 200 via the seven-way plug 235 without the need of connecting the trailer lights to a conventional tow vehicle.

Intermediate the power supply interface 210 and the terminals 240 is a conventional fuse 295. The fuse 295 functions to protect the terminal assembly circuit 200 from any over-current incidence that may result in damage to the terminal assembly circuit 200. A ground terminal 290 is electrically coupled to each of the plurality of terminals 240.

Opposedly mounted proximate the central portion 285 of the seven-way plug 235 are a right turn signal terminal 250 and a left turn signal terminal 270 that function to electrically couple with the turn signal lights of a trailer. The right turn signal terminal 250 and left turn signal terminal 270 are electrically coupled with three-way switch 230 that is intermediate the power terminal 225 and the turn signal terminals 272. The switch 230 is a conventional three-way switch that is operable such that power is supplied to the corresponding terminals thereby illuminating the corresponding trailer light. If the corresponding trailer light does not illuminate or light, this indicates a problem or failure with the corresponding light.

The flashing unit 220 functions to cycle the current present in the portion of the terminal assembly circuit 200 in order to produce a repetitive flashing of a turn signal light of a trailer. The flashing unit 220 is further electrically coupled to the tail light terminal 280 to draw power. The tail light terminal 280 functions to provide current to the tail lights of a conventional trailer light system.

Intermediate the turn signals terminals 272 mounted proximate the central portion 285 of the seven-way plug is the reverse light terminal 260. The reverse light terminal 260 functions to provide current to the reverse light subsequent to the engagement of a conventional trailer light system with the trailer light testing device 100.

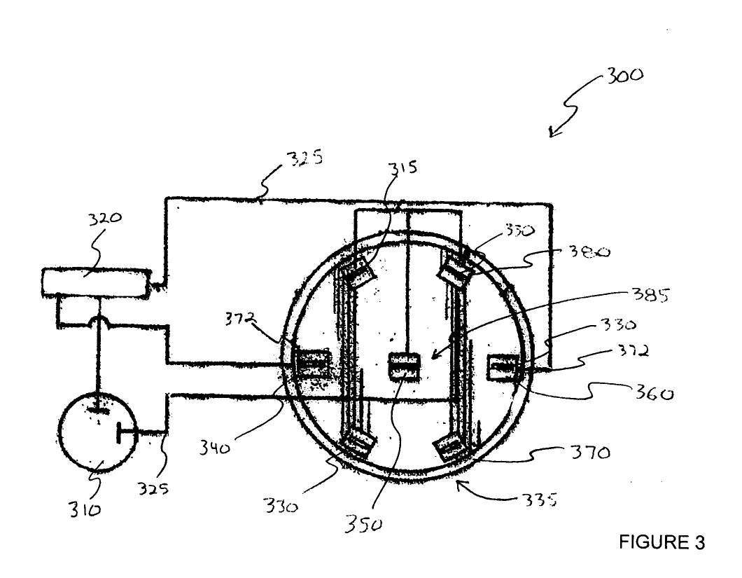

Illustrated in FIG. 3 submitted herewith is an alternative embodiment of a terminal assembly circuit 300 such as could be embodied by light testing device 100. As illustrated, the terminal assembly circuit 300 includes a power supply terminal 315, flashing unit 310, three-way switch 320, terminals 330, wire 325 and a ground terminal 370.

The terminal assembly circuit 300 is integrated into a conventional seven-way plug 335 containing a plurality of terminals 330. The terminals 330 are conventional female receptacles that are manufactured of electrically conductive material according to standard practices to those skilled in the art. The terminals 330 are of suitable size and shape to electrically couple with a conventional seven-way plug of a trailer light system. Those skilled in the art will recognize that the terminals could be configured to electrically couple with a conventional four-way or six way plug of a conventional trailer light system.

The power supply terminal 315 is electrically coupled with a conventional twelve volt power supply such as but not limited to a twelve volt DC battery that is substantially disposed within the housing 10 of the trailer light testing device 100. Those skilled in the art will recognize that numerous different power supplies could be utilized to supply power to the terminal assembly circuit 300.

The power supply terminal 315 is electrically coupled to all of the terminals 330 utilizing wire 325 constructed of electrically conductive material according to standard practices known to those skilled in the art. The power supply terminal 315 engages with a standard power supply in order to provide the needed current to operate and test conventional trailer lights that are electrically coupled to the terminal assembly circuit 300 via the seven-way plug 335 without the need of connecting the trailer lights to a conventional tow vehicle. A ground terminal 370 is electrically coupled to each of the plurality of terminals 330 for providing a second independent ground path for electrical current. The ground terminal 370 is further designed to isolate grounding issues with a conventional trailer light connector that is engaged with the terminal assembly circuit 300.

Opposedly mounted proximate the central portion 385 of the seven-way plug 335 are a right turn signal terminal 340 and a left turn signal terminal 360 that function to electrically couple with the turn signal lights of a trailer operably connected to the trailer light testing device 100. The right turn signal terminal 340 and left turn signal terminal 360 are electrically coupled with a switch 320 that is intermediate the power supply terminal 315 and the turn signal terminals 372. The switch 320 is a conventional three-way switch that is operable in such that the power is supplied to the corresponding terminals thereby illuminating the corresponding trailer light. If the corresponding trailer light does not illuminate or light, this indicates a problem or failure with the corresponding light.

The flashing unit 310 functions to control the repetitive flashing of a turn signal light of a trailer by cycling the current in the portion of the terminal assembly circuit 300 intermediate the switch 320 and the turn signal terminals 372. The flashing unit 310 is further electrically coupled to the tail light terminal 380. The tail light terminal 380 functions to provide current to the tail lights of a conventional trailer light system.

Intermediate the turn signals terminals 372 mounted proximate the central portion 385 of the seven-way plug is the reverse light terminal 350. The reverse light terminal 350 is electrically coupled to the reverse lights of a conventional trailer light system subsequent the trailer light plug engaging with the seven way plug 335 thereby functioning to provide current to the reverse lights of a conventional trailer light system.

Referring in particular to FIGS. 1 and 3, a description of the operation of the present invention is as follows. In use, a user will couple a conventional trailer light plug, such as but not limited to a seven-way plug, to the terminal assembly 40 thereby electrically engaging the plurality of terminal leads 50 with the standard leads of the conventional seven-way trailer light plug. Subsequent to operably connecting the terminal assembly 40 with the trailer light plug, the trailer light testing device 100 utilizes a standard twelve volt power supply that is substantially disposed within the housing 10 to provide the necessary current to electrically operate the plurality of lights on a conventional trailer. The user will utilize the switch 320 to engage the portion of the terminal assembly circuit 300 to electrically operate the turn signal terminals 372. Once all of the desired lights of the trailer light system have been tested by the trailer light testing device 100, the user disengages the trailer light system plug from the terminal assembly 40.

In the preceding detailed description, reference has been made to the accompanying drawings that form a part hereof, and in which are shown by way of illustration specific embodiments in which the invention may be practiced. These embodiments, and certain variants thereof, have been described in sufficient detail to enable those skilled in the art to practice the invention. It is to be understood that other suitable embodiments may be utilized and that logical changes may be made without departing from the spirit or scope of the invention. The description may omit certain information known to those skilled in the art. The preceding detailed description is, therefore, not intended to be limited to the specific forms set forth herein, but on the contrary, it is intended to cover such alternatives, modifications, and equivalents, as can be reasonably included within the spirit and scope of the appended claims.

What is claimed is:

1. A trailer light test device comprising:
a housing;
a terminal assembly, said terminal assembly configured to be positioned within said housing, said terminal assembly being adapted to be operably connected to a trailer light wiring connector of a trailer;
said terminal assembly further including a terminal assembly circuit, said terminal assembly circuit having a plurality of electrical terminals configured to be electrically coupled with the trailer light wiring connector and lights of the trailer; and
wherein said terminal assembly circuit provides electrical current subsequent to coupling of said terminal assembly with the trailer light wiring connector of a trailer and further wherein a light is illuminated indicating no problem with the particular light.

2. The trailer light test device as recited in claim 1, wherein said terminal assembly is configured to operably connect with a conventional seven-way plug of a trailer light system.

3. The trailer light test device as recited in claim 2, wherein said electrical terminals in said terminal assembly are female so as to facilitate operable engagement with the seven-way plug of a conventional trailer light system.

4. The trailer light test device as recited in claim 3, wherein said terminal assembly circuit includes two turn signal terminals for operably engaging with the turn signal lights of a conventional trailer lighting system.

5. The trailer light test device as recited in claim 4, wherein said two turn signal terminals are operably controlled by a flashing unit.

6. The trailer light test device as recited in claim 5, and further including a switch, said switch being operably connected to said turn signal terminals, said switch configured to control electrical current to said turn signal terminals.

7. The trailer light test device as recited in claim 6, wherein said lighting test device is powered by a twelve volt DC power supply that is substantially disposed within said housing.

8. A trailer light testing device for selectively providing power to at least one of a plurality of trailer lights, comprising:
a housing, said housing having at least one wall defining an interior volume, said housing having a first and second end;
a terminal assembly, said terminal assembly configured to be positioned proximate said first end of said housing, said terminal assembly being adapted to be operably connected to a trailer light wiring connector of a trailer;
said terminal assembly further including a terminal assembly circuit, said terminal assembly circuit including a power terminal for connection to a power supply, said terminal assembly circuit having a plurality of electrical terminals electrically coupled with said power terminal, said terminal assembly circuit being configured to be operably engaged with the trailer light wiring connector and plurality of trailer lights of the trailer; and
wherein said terminal assembly circuit selectively provides electrical current to at least one of the plurality of trailer lights and further wherein the illumination of the at least one of the plurality of trailer lights indicates a passing condition for the at least one of the plurality of trailer lights.

9. The trailer light testing device as recited in claim 8, wherein said terminal assembly is configured to mateably engage with a seven-way plug of a trailer lighting system.

10. The trailer light testing device as recited in claim 9, wherein said electrical terminals include a right turn signal terminal, a left turn signal terminal, a tail light terminal, a reverse light terminal and a ground terminal, said electrical terminals being female so as to operably engage with a conventional seven-way plug of a trailer light system.

11. The trailer light testing device as recited in claim 10, and further including a switch, said switch being mounted on said housing, said switch having a first, second and third position, said switch being intermediate said power terminal and said left turn signal terminal and said right turn signal terminal along said terminal assembly circuit, said switch for controlling the current flow to said right turn signal terminal and said left turn signal terminal.

12. The trailer light testing device as recited in claim 11, and further including an automotive light flashing unit, said automotive light flashing unit being operably connected to said right turn signal terminal and said left turn signal terminal, said automotive light flashing unit for controlling the cycle of electrical current to said right turn signal terminal and said left turn signal terminal.

13. The trailer light testing device as recited in claim 12, wherein said trailer light testing device is powered by a twelve volt DC power supply.

14. The trailer light testing device as recited in claim 13, and further including a lid configured to substantially cover said terminal assembly.

15. A recreational vehicle trailer light testing device, comprising:
a housing, said housing having at least one wall defining an interior volume, said housing having a first and second end;
a terminal assembly, said terminal assembly configured to be positioned proximate said first end of said housing, said terminal assembly being generally annular in shape, said terminal assembly being adapted to be operably connected to a trailer light wiring connector of the recreational vehicle trailer;
said terminal assembly further includes, a terminal assembly circuit, said terminal assembly circuit having a seven electrical terminals being configured as female receptacles, said terminal assembly circuit being adapted to have electrical current supplied thereto via a power terminal, said terminal assembly circuit having six electrical terminals electrically coupled with said power terminal, said terminal assembly circuit being configured to be operably engaged with the recreational vehicle trailer light wiring connector,
wherein said terminal assembly circuit provides electrical current to the lighting system of the trailer subsequent to coupling of said terminal assembly with the trailer light wiring connector of a trailer.

16. The recreational vehicle trailer light testing device as recited in claim 15, wherein said electrical terminals include a right turn signal terminal, a left turn signal terminal, a tail light terminal, a reverse light terminal and a ground terminal, said electrical terminals being configured so as to operably engage with a conventional seven-way plug of a trailer light system, said ground terminal being electrically coupled with each of said electrical terminals for providing an independent ground path for electrical current.

17. The recreational vehicle trailer light testing device as recited in claim 16, and further including a switch, said switch being mounted on said housing, said switch having a first, second and third position, said switch being intermediate said power terminal and said left turn signal terminal and said right turn signal terminal along said terminal assembly circuit, said switch for controlling the current flow to said right turn signal terminal and said left turn signal terminal.

18. The recreational vehicle trailer light testing device as recited in claim 17, and further including an automotive light flashing unit, said automotive light flashing unit being operably connected to said right turn signal terminal and said left turn signal terminal, said automotive light flashing unit for controlling the cycle of electrical current to said right turn signal terminal and said left turn signal terminal.

19. The recreational vehicle trailer light testing device as recited in claim 18, and further including a lid, said lid being hingedly mounted proximate said first end of said housing, said lid configured to substantially cover said terminal assembly.

20. The recreational vehicle trailer light testing device as recited in claim 19, wherein said trailer light testing device is powered by a twelve volt DC power supply.
